(19) United States
(12) Patent Application Publication
(10) Pub. No.: US 2005/0095750 A1
(43) Pub. Date: May 5, 2005

(54) Wafer level transparent packaging

(75) Inventors: Jian-Wen Lo, Banciao City (TW); Shin-Hua Chao, Kaohsiung City (TW); Chia-Yi Hu, Kaohsiung City (TW)

Correspondence Address: TROXELL LAW OFFICE PLLC;SUITE 1404, 5205 LEESBURG PIKE, FALLS CHURCH, VA, 22041, US

(73) Assignee: Advanced Semiconductor Engineering, Inc.

(21) Appl. No.: 10/948,214

(22) Filed: Sep. 24, 2004

(30) Foreign Application Priority Data
Sep. 26, 2003 (TW) 092126690

(51) Int. Cl. H01L 21/50; H01L 21/44; H01L 21/46; H01L 21/48; H01L 21/301; H01L 21/78

(52) U.S. Cl. 438/114; 438/464; 438/465

(57) ABSTRACT

A process for manufacturing transparent semiconductor packages is disclosed. A wafer having an active surface and a back surface is provided. A plurality of first redistribution lines are formed on the active surface of the wafer to connect the bonding pads of the chips. A transparent polymer is formed over the active surface of the wafer to cover the first redistribution lines. A plurality of first grooves are formed corresponding to the scribe lines and in the back surface of the wafer. Preferably, a back coating is then formed over the back surface to fill the first grooves. Next, a plurality of second grooves are formed corresponding to the first grooves and through the back coating such that the first redistribution lines have exposed portions. A plurality of second redistribution lines on the back coating can extend to the exposed portions of the corresponding first redistribution lines for connecting solder balls on the back surface.

### FIELD OF THE INVENTION

The present invention relates to semiconductor packaging in wafer level, more particularly to a wafer level transparent packaging process with double side connection.

### BACKGROUND OF THE INVENTION

Wafer level packaging is one of the new semiconductor packaging techniques for future advanced packaging applications. Since there are so many kinds of semiconductor products, conventionally, the well-known wafer level packaging methods cannot be used for all semiconductor products, especially for packaging image sensor chips. Traces or external terminals, such as bumps or solder balls, should not block the light path of the sensing region on the active surfaces of the image sensor chips to achieve better transparency.

A chip scale packaging method for optical image sensor integrated circuits is disclosed in R.O.C. Taiwan Patent No. 465,054 to Foster. Micro lens are formed on a wafer with image sensor integrated circuits, and an adhesive matrix having openings is placed on top of the wafer to secure a cover glass. However, the method keeps silent about manufacturing RDL (redistribution layer) or external terminals on the wafer.

Another conventional transparent packaging method in wafer level is disclosed in U.S. Pat. No. 6,040,235 to Badehi. A cover glass is attached to the active surface of a wafer by epoxy adhesive. An epoxy layer and an insulating packaging layer are formed on the back surface of the wafer after forming grooves on the back surface of the wafer. The grooves expose the metal pads of the wafer, and then metal contacts are disposed on the inclined edges of the cover glass. In this conventional transparent wafer level packaging method, bubbles will easily generate in the epoxy adhesive between the active surface of the wafer and the cover glass when the cover glass is pressed where these bubbles will cause light scattering and defects for image sensor chips. Moreover, chip cracking and backside chipping will easily occur when cutting the wafer and the cover glass.

### SUMMARY

The main object of the present invention is to provide a transparent packaging process in wafer level, including the formations of a transparent polymer and redistribution lines. A plurality of grooves are formed in the back surface of the wafer. A transparent polymer is formed over the active surface of a semiconductor wafer and covers the first redistribution lines on the active surface without adhering a glass to a wafer, thereby to solve the known problems of bubbles and light scattering caused by the adhesive between wafer and the glass and to eliminate the cutting crack with respect to the glass and the wafer and to improve the throughput of the transparent semiconductor packages with lighter weights and thinner profiles.

The secondary object of the present invention is to provide a transparent packaging process in wafer level, including the steps of formation of a plurality of first and second grooves for redistribution lines. The first grooves are formed in the back surface of a semiconductor wafer, and then a back coating is formed to fill the first grooves. The second grooves are formed through the back coating to expose portions of first redistribution lines on the active surface of a semiconductor wafer. Next, the second redistribution lines can be formed on the back coating to connect the exposed portions of the first redistribution lines without contacting the semiconductor wafer so as to achieve double-sided electrical connection.

The transparent packaging process in wafer level in accordance with the present invention comprises the steps as follows. Initially, a semiconductor wafer including a plurality of chips and a plurality of scribe lines formed between the chips is provided. The semiconductor wafer has an active surface and a back surface. A plurality of first redistribution lines are formed on the active surface and extend from the bonding pads of the chips to the scribe lines. Preferably, each of the chips has an image sensing region on the active surface. Without placing a conventional glass on a wafer, a transparent polymer is formed over the active surface of the semiconductor wafer to cover the first redistribution lines. Thereafter, a plurality of first grooves are formed corresponding to the scribe lines and in the back surface of the semiconductor wafer. Next, a back coating is formed over the back surface of the semiconductor wafer to fill the first grooves. Then, a plurality of second grooves are formed corresponding to the scribe lines and through the back coating to expose portions of the first redistribution lines. A plurality of second redistribution lines on the back coating can extend to the exposed portions of the corresponding first redistribution lines in the second grooves. Moreover, a semiconductor device is disclosed from the transparent packaging process in wafer level.

### DESCRIPTION OF THE DRAWINGS

FIG. 1 is a flow chart of the transparent packaging process in wafer level according to the present invention.

FIG. 2A to FIG. 2J are the cross-sectional views illustrating a wafer in fabrication processes according to an embodiment of the present invention.

### DETAILED DESCRIPTION OF THE PRESENT INVENTION

Referring to the drawings attached, the present invention will be described by means of the embodiment(s) below.

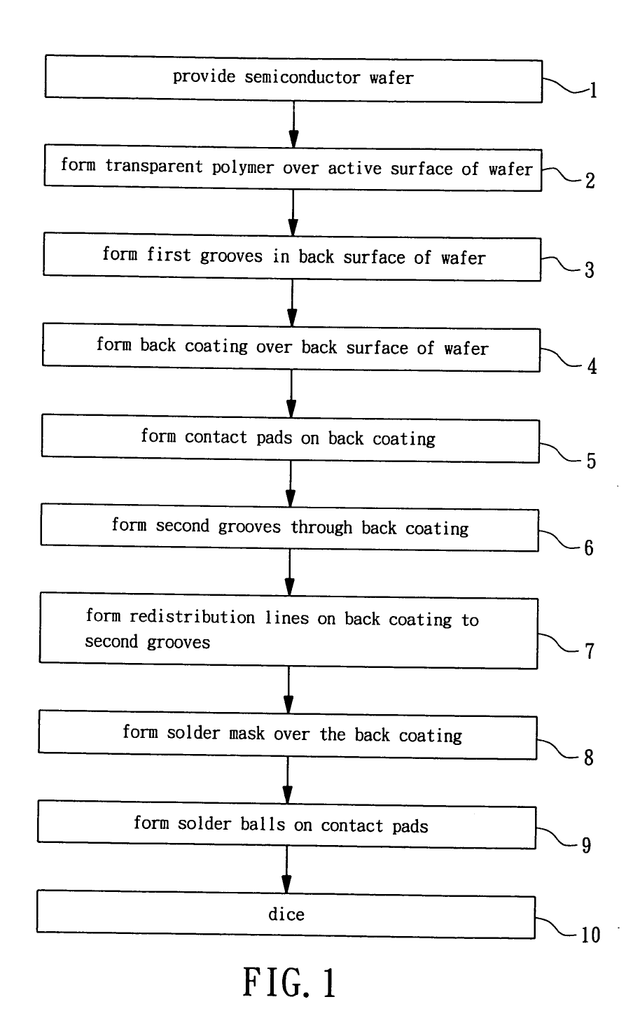

Referring to FIG. 1, the transparent packaging process in wafer level in accordance with the present invention comprises: step 1 of “provide semiconductor wafer”, step 2 of “form transparent polymer over active surface of wafer”, step 3 of “form first grooves in back surface of wafer”, step 4 of “form back coating over back surface of wafer”, step 5 of “form contact pads on back coating”, step 6 of “form second grooves through back coating”, step 7 of “form redistribution lines on back coating to second grooves”, step 8 of “form solder mask over the back coating”, step 9 of “form solder balls on contact pads”, step 10 of “dice”.

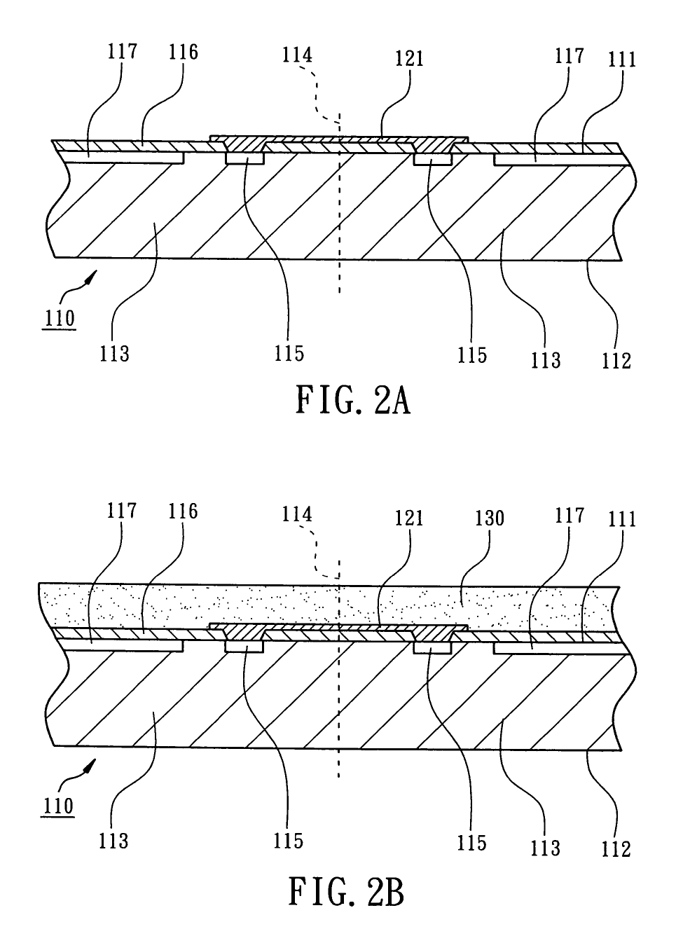

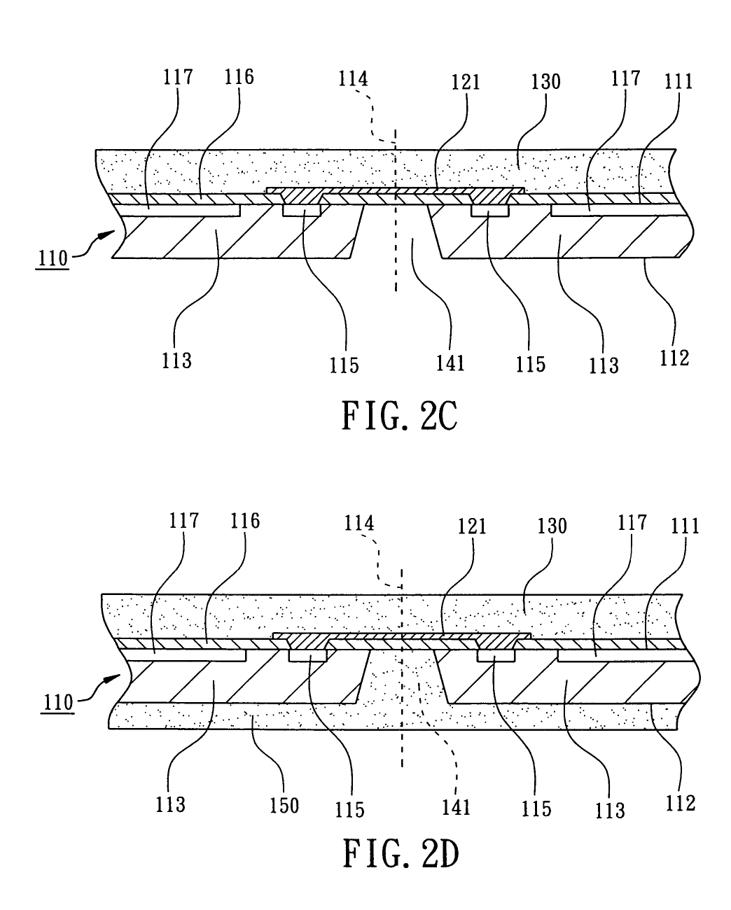

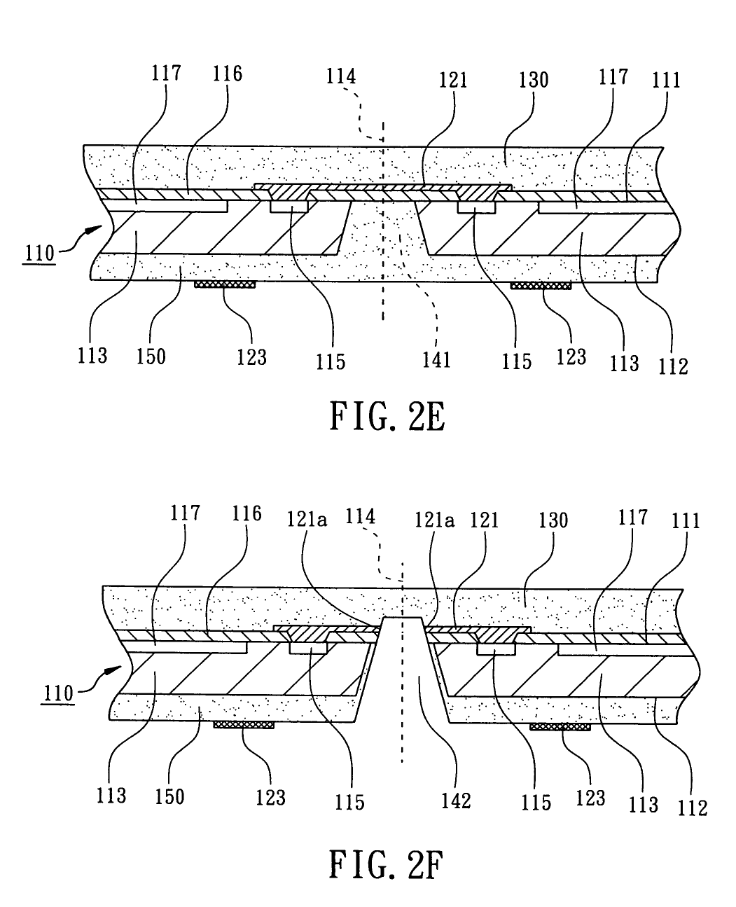

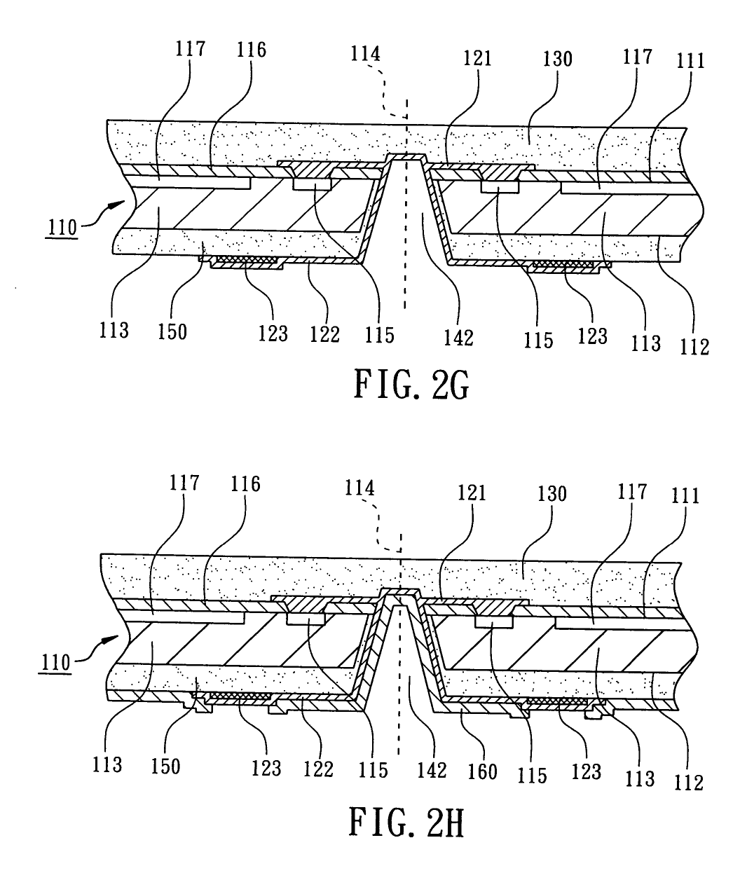

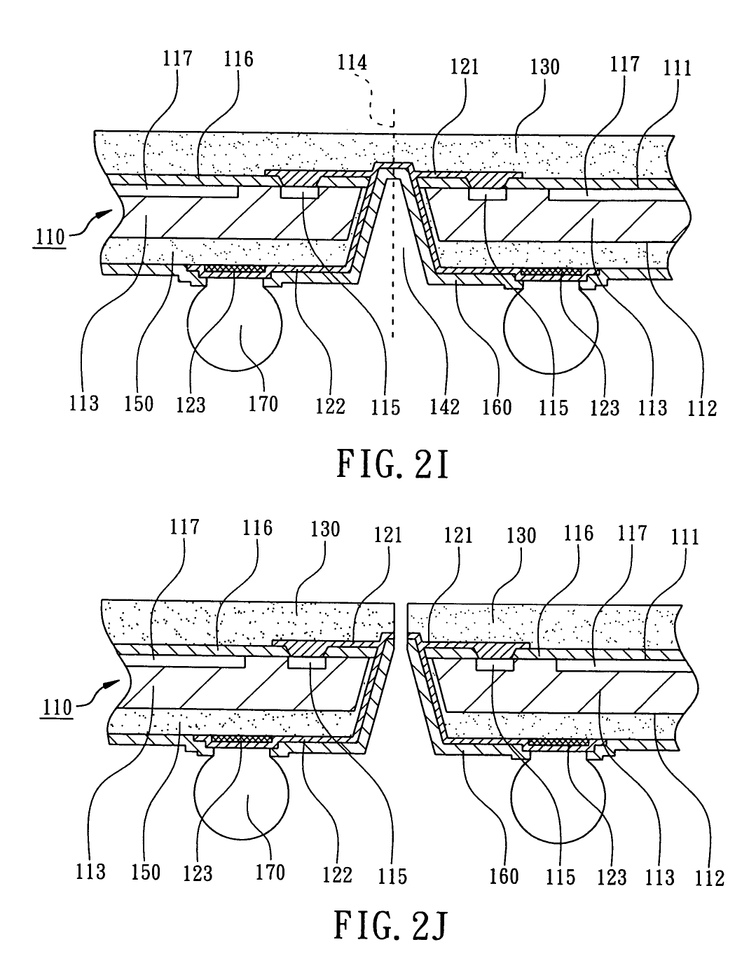

Initially, in the step 1, a semiconductor wafer 110 is provided as shown in FIG. 2A. The semiconductor wafer 110 has an active surface 111 and a back surface 112 and also includes a plurality of integrally connected chips 113 and a plurality of scribe lines 114 between the chips 113. In this embodiment, the chips 113 are CMOS image sensor chips and each has an image sensor region 117 and a plurality of bonding pads 115 on the active surface 111. Normally there is a passivation layer 116 on the active surface 111. A plurality of first redistribution lines 121 are formed on the active surface 111 and connected to the respective bonding pads 115 by means of sputtering or other metal deposition methods. Moreover, the first redistribution lines 121 extend to the scribe lines 114.

In the step 2, a transparent polymer 130 is formed, as shown in FIG. 2B, over the active surface 111 of the semiconductor wafer 110 by spin coating, printing or molding techniques. The transparent polymer 130 may be selected from the group consisting of polyimide (PI) or benzocyclobutene (BCB). Among the method, spin-coating in vacuum and molding is more feasible for the transparent polymer 130 that allows the transparent polymer 130 to be closely contact the active surface 111 of the semiconductor wafer 110 without bubbles and voids. The transparent polymer 130 also covers the first redistribution lines 121 for protection, and has a planar upper surface. Moreover, the transparent polymer 130 applied in step 2 is thinner than the conventional glass including adhesive.

In the step 3, a plurality of first grooves 141 are formed, as shown in FIG. 2C, corresponding to the foregoing scribe lines 114 and in the back surface 112 of the semiconductor wafer 110. One of the forming methods of the first grooves 141 is chemical etching using silicon-etching solution so that the semiconductor material of the semiconductor wafer 110 at the scribe lines 114 is removed, and the first redistribution lines 121 and the transparent polymer 130 are reserved. In this embodiment, the first grooves 141 are V-shaped in cross section, i.e., the first grooves 141 have slopes with certain angles. Therefore, each chip 113 has a plurality of chamfered edges adjacent to the back surface 112 for extension of the second redistribution lines 122. Preferably, the back surface 112 of the semiconductor wafer 110 may be lapped to obtain a suitable thickness during step 3 of forming the first grooves.

In the step 4, a back coating 150 is formed, as shown in FIG. 2D, over the back surface 112 of the semiconductor wafer 110 by spin coating, printing or molding techniques. Material of the back coating 150 may be the same with or different from the material of the foregoing transparent polymer 130. The back coating 150 may be transparent, opaque, or semi-opaque, made of proper dielectric materials. The back coating 150 fills the first grooves 141. Alternatively, a thin insulation layer, such as oxide layer made from the wafer 110 or external cover layer can be applied to displace the back coating 150 for forming the second grooves 142.

If necessary, step 5 should be executed as shown in FIG. 2E. A plurality of contact pads 123 are disposed on the back coating 150. A process for forming the contact pads 123 includes attaching a copper foil to the back coating 150 and etching the copper foil to form the contact pads 123 in array on the back coating 150.

When step 6 is performed, as shown in FIG. 2F, a plurality of second grooves 142 are formed corresponding to the scribe lines 114 and through the back coating 150. Preferably, the second grooves 142 are formed by sawing without cutting through the transparent polymer 130. The second grooves 142 are deeper and narrower than the first grooves 141 such that the first redistribution lines 121 have exposed portions 121a in the second grooves 142. However, the remaining portions of the back coating 150 in the second grooves 142 still cover the sidewalls of the chips 113 formed by the first grooves 141. The semiconductor material of the semiconductor wafer 110 is not exposed out of the second grooves 142. It is desirable that the second grooves 142 are also V-shaped in cross section same as the first grooves, the slopes of the second grooves 142 are parallel to the sidewalls of the chips 113 formed by the first grooves 141.

In the step 7, a plurality of second redistribution lines 122 can be shown in FIG. 2G. The second redistribution lines 122 are formed on the back coating 150 and extend to the second grooves 142. One ends of the second redistribution lines 122 are connected to the contact pads 123 and the other ends of the second redistribution lines 122 extend to the slopes of the second grooves 142 to connect the exposed portions 121a of the corresponding first redistribution lines 121 so that the bonding pads 115 on the active surface 111 are electrically connected to the contact pads 123 on the back coating 150. Preferably, step 8 is executed as shown in FIG. 2H, a solder mask 160 or a protective cover layer is formed over the back coating 150 and the second grooves 142 to cover the second redistribution lines 122 except for the contact pads 123. Preferably, step 9 is further included. Referring to FIG. 2I, a plurality of solder balls 170 are mounted onto the contact pads 123. After completing the double side encapsulation and connection from the active surface 111 to the back surface 112, dicing step 10 may be executed. Referring to FIG. 2J, the transparent polymer 130 is diced along the scribe lines 114 to obtain a plurality of individual transparent wafer level packages, particularly useful to transparently packaging image sensor chips in wafer level.

Transparent wafer level package made from the process mentioned above, mainly comprises a chip 113, a transparent polymer 130 and a back coating 150. The chip 113 has an active surface 111 and a back surface 112. A plurality of first redistribution lines 121 connect the bonding pads 115 and extend to the periphery of the active surface 111 of the chip 113. The transparent polymer 130 is formed over the active surface 111 of the chip 113 to cover the first redistribution lines 121. The back coating 150 is formed over the back surface 112 of the chip 113 to cover the back surface 112. A plurality of second redistribution lines 122 are formed on the back coating 150 and extend to the periphery of the back coating 150 to connect the corresponding first redistribution lines 121. Moreover, a plurality of contact pads 123 are formed on the back coating 150 and a plurality of solder balls 170 are mounted onto the contact pads 123 so as to electrically connect to the bonding pads 115 via the first redistribution lines 121 and the second redistribution lines 122.

Accordingly, the transparent packaging technique in wafer level in accordance with the present invention not only can solve the known problems of bubbles and photo-scattering caused by the adhesive between the glass and the wafer, but also can greatly reduce the dicing times, back chipping and chip cracking with respect to conventional glass attachment. The transparent packages in wafer level also can be improved in throughput and have lighter and thinner profiles. While the present invention has been particularly illustrated and described in detail with respect to the preferred embodiments thereof, it will be clearly understood by those skilled in the art that various changed in form and details may be made without departing from the spirit and scope of the present invention.

1. A process for manufacturing transparent semiconductor packages, comprising:
providing a semiconductor wafer having an active surface and a back surface, the wafer including a plurality of chips with bonding pads and a plurality of scribe lines between the chips;
forming a plurality of first redistribution lines on the active surface, the first redistribution lines extending from the bonding pads to the scribe lines;
forming a transparent polymer over the active surface to cover the first redistribution lines;
forming a plurality of first grooves corresponding to the scribe lines and in the back surface;
forming a back coating over the back surface to fill the first grooves;
forming a plurality of second grooves corresponding to the scribe lines and through the back coating such that the first redistribution lines have exposed portions; and
forming a plurality of second redistribution lines on the back coating, the second redistribution lines extending to the exposed portions of the corresponding first redistribution lines in the second grooves.

2. The process in accordance with claim 1, wherein the second grooves are V-shaped in cross section.

3. The process in accordance with claim 1, wherein the transparent polymer is selected from the group consisting of polyimide and benzocyclobutene.

4. The process in accordance with claim 1, further comprising the step of forming a solder mask over the back coating and the second redistribution lines.

5. The process in accordance with claim 1, further comprising the step of forming a plurality of contact pads on the back coating.

6. The process in accordance with claim 5, further comprising the step of forming a plurality of solder balls on the contact pads.

7. The process in accordance with claim 1, further comprising the step of dicing the transparent polymer.

8. The process in accordance with claim 1, wherein the chips are image sensor chips each having a sensing region on the active surface of the semiconductor wafer.

9. The process in accordance with claim 1, further comprising the step of grinding the back surface of the semiconductor wafer prior to the step of forming the back coating.

10. The process in accordance with claim 1, wherein the second grooves are deeper than the first grooves.

11. The process in accordance with claim 1, wherein the second grooves are narrower than the first grooves.

12. A process for manufacturing transparent semiconductor packages, comprising:
providing a semiconductor wafer having an active surface and a back surface, the wafer including a plurality of chips with bonding pads and a plurality of scribe lines between the chips;
forming a plurality of first redistribution lines on the active surface, the first redistribution lines extending from the bonding pads to the scribe lines;
forming a transparent polymer over the active surface to cover the first redistribution lines;
forming a plurality of grooves corresponding to the scribe lines and through the semiconductor wafer such that the first redistribution lines have exposed portions; and
forming a plurality of second redistribution lines on the back surface of the semiconductor wafer, the second redistribution lines extending to the exposed portions of the corresponding first redistribution lines in the grooves.

13. The process in accordance with claim 12, wherein the transparent polymer is selected from the group consisting of polyimide and benzocyclobutene.

14. The process in accordance with claim 12, further comprising the step of forming a plurality of contact pads on the back surface of the wafer.

15. A semiconductor device comprising:
a semiconductor chip having an active surface and a back surface, the chip including a plurality of bonding pads on the active surface;
a plurality of first redistribution lines formed on the active surface and extending from the bonding pads to the periphery of the active surface;
a transparent polymer formed over the active surface to cover the first redistribution lines;
a back coating formed over the back surface; and
a plurality of second redistribution lines formed on the back coating and connecting the corresponding first redistribution lines.

16. The device in accordance with claim 15, wherein the transparent polymer is selected from the group consisting of polyimide and benzocyclobutene.

17. The device in accordance with claim 15, wherein the chip has a plurality of chamfered edges adjacent to the back surface for extension of the second redistribution lines.

18. The device in accordance with claim 17, wherein the back coating covers the chamfered edges.

19. The device in accordance with claim 15, further comprising a solder mask formed over the back coating and the second redistribution lines.

20. The device in accordance with claim 15, further comprising a plurality of contact pads on the back coating.

21. The device in accordance with claim 20, further comprising a plurality of solder balls on the contact pads.

22. The device in accordance with claim 15, wherein the chip is an image sensor chip having a sensing region on the active surface.

23. A semiconductor device comprising:
a semiconductor chip having an active surface and a back surface, the chip including a plurality of bonding pads on the active surface;
a plurality of first redistribution lines formed on the active surface and extending from the bonding pads to the periphery of the active surface;
a transparent polymer formed over the active surface to cover the first redistribution lines; and
a plurality of second redistribution lines formed on the back surface and connecting the corresponding first redistribution lines.

24. The device in accordance with claim 23, wherein the transparent polymer is selected from the group consisting of polyimide and benzocyclobutene.

25. The device in accordance with claim 23, wherein the chip has a plurality of chamfered edges adjacent to the back surface for extension of the second redistribution lines.
